(19) United States
(12) Patent Application Publication
(10) Pub. No.: US 2015/0303363 A1
(43) Pub. Date: Oct. 22, 2015

(54) THERMOELECTRIC CONVERSION ELEMENT, USE OF THE SAME, AND METHOD OF MANUFACTURING THE SAME

(71) Applicants: NEC CORPORATION, Tokyo (JP); NEC TOKIN CORPORATION, Miyagi (JP)

(72) Inventors: Akihiro KIRIHARA, Tokyo (JP); Masahiko ISHIDA, Tokyo (JP); Shigeru KOUMOTO, Tokyo (JP); Koichi KONDO, Miyagi (JP); Naoharu YAMAMOTO, Miyagi (JP)

(73) Assignees: NEC CORPORATION, Tokyo (JP); NEC TOKIN CORPORATION, Miyagi (JP)

(21) Appl. No.: 14/648,230

(22) PCT Filed: Oct. 11, 2013
(86) PCT No.: PCT/JP2013/078401

§ 371 Date: May 28, 2015

(30) Foreign Application Priority Data
Dec. 6, 2012 (JP) 2012-267483

(51) Int. Cl. H01L 35/02; H01L 43/14; H01L 43/10; H01L 37/04; H01L 43/04

(52) U.S. Cl. CPC H01L 35/02; H01L 37/04; H01L 43/04; H01L 43/10; H01L 43/14

(57) ABSTRACT

An object of the present invention is to provide a thermoelectric conversion element that can demonstrate satisfactory thermoelectric conversion performance, and also has flexibility or can be mounted on a surface having irregularities or a curved surface, a method of manufacturing such a thermoelectric conversion element, and a method of using such a thermoelectric conversion element. A thermoelectric conversion element according to the present invention includes a columnar crystal ferrite layer and an electromotive film formed on the columnar crystal ferrite layer. The electromotive film is configured to generate an electromotive force in an in-plane direction by an inverse spin Hall effect. Columnar crystal grains of the columnar crystal ferrite layer include a major axis a of not less than 200 nm and a minor axis b of not more than 500 nm where a>b.

### TECHNICAL FIELD

The present invention relates to an apparatus for generating electric power from a temperature gradient and a method of generating electric power from a temperature gradient.

### BACKGROUND OF INVENTION

Expectations of thermoelectric conversion elements have grown as one of smart energy techniques directed to the sustainable society. Heat is the most common energy source that is available from various situations, such as body temperature, solar heat, engines, and industrial exhaust heat. Therefore, thermoelectric converter elements are expected to become more important in future for efficiency enhancement in energy use for a low-carbon economy or for applications of power supply to ubiquitous terminals, sensors, or the like.

A wide variety of heat sources, such as body heat of humans or animals, lighting (fluorescent lamps and street lamps), IT equipment (displays and servers), automobiles (parts around engines and exhaust pipes), public facilities (waste incinerators and water service pipes), buildings (walls, windows, and floors), and natural structures (plants, rivers, and ground), can be used for thermoelectric conversion elements.

In thermoelectric conversion, a device should be brought into intimate contact with such a heat source, and a generated temperature difference should be used efficiently. However, most of heat sources include curved surfaces or irregularities. Therefore, it is desirable for a thermoelectric conversion element to have flexibility (pliability) so that it can readily be provided on heat sources having various shapes, or to have capability of being provided on curved surfaces or surfaces having irregularities.

However, a general thermoelectric conversion element comprises a complicated structure in which a large number of thermoelectric modules having a p-n junction are arranged and electrically connected in series to each other. Therefore, if even one junction or wire is broken when the thermoelectric conversion element is bent to a large degree, the thermoelectric conversion function of deriving thermoelectromotive forces is impaired. Accordingly, such pliable elements still have problems in a highly reliable operation.

Under such circumstances, in recent years, there have been reported thermoelectric conversion elements using the “spin Seebeck effect,” which generates currents of spin angular momentum (spin currents) when a temperature gradient (temperature difference) is applied to a magnetic material (see Patent Literatures 1-2 and Non-Patent Literatures 1-2).

Those thermoelectric conversion elements convert spin currents induced in a magnetic body by the spin Seebeck effect into electric currents by the “inverse spin Hall effect” in an electromotive film to derive thermoelectromotive forces. Thus, the thermoelectric conversion elements are configured to perform “thermoelectric conversion,” which generates electricity from a temperature gradient.

In a thermoelectric conversion element using the spin Seebeck effect, an “insulating magnetic body (magnetic insulator),” which permits no electric current to flow therethrough, can be used as a thermoelectric material that holds a temperature difference. Such a magnetic insulator has a thermal conductivity lower than metals or semiconductors. Therefore, such a magnetic insulator may possibly achieve an effective thermoelectric conversion by holding a large temperature difference therein.

For example, according to Patent Literature 2, a thermoelectric conversion element is formed by using monocrystalline yttrium iron garnet (YIG), which is a kind of garnet ferrites, for a magnetic insulator, and a platinum (Pt) wire for an electromotive film, thereby performing thermoelectric conversion.

Furthermore, Non-Patent Literature 1 succeeded in thermoelectric conversion using the spin Seebeck effect with an element in which a polycrystalline ferrite with randomly oriented grain boundaries is used for a magnetic insulator.

Moreover, according to Non-Patent Literature 2, a bismuth substitution yttrium iron garnet (Bi:YIG) thin film formed by application is used for a magnetic body, and a platinum (Pt) thin film is used for an electromotive film. Thus, a thermoelectric conversion element is formed of a simple two-layer film structure.

In any of the aforementioned cases, when an insulating material such as a ferrite is used as a magnetic body contributing to the spin Seebeck effect, the thermal resistance can be increased as compared to metals or semiconductors. It becomes easier to apply a temperature difference to such a portion. Thus, to use an insulating material as a magnetic body is preferable in view of the thermoelectric conversion performance.

Furthermore, as shown in Non-Patent Literature 2, a spin Seebeck type thermoelectric conversion element can obtain a large thermoelectromotive force simply by increasing an area of a film structure. Therefore, the spin Seebeck type thermoelectric conversion element does not need to join a large number of thermoelectric modules unlike a general thermoelectric conversion element.

Accordingly, the probability of occurrence of deficiencies such as breakage of a junction may remarkably be reduced as compared to conventional thermoelectric conversion elements including a complicated structure. Thus, implementation of a flexible thermoelectric conversion element having high reliability and installation on a curved surfaces and surfaces having irregularities are expected.

### PRIOR ART LITERATURE

### Patent Literature

Patent Literature 1: JP-A 2009-130070
Patent Literature 2: WO 2009/151000

### Non-Patent Literature

Non-Patent Literature 1: Appl. Phys. Lett. 97, 262504 (2010)
Non-Patent Literature 2: WO 2009/151000

### SUMMARY OF INVENTION

### Problem(s) to be Solved by Invention

However, a conventional spin current thermoelectric conversion element using a monocrystalline ferrite or a polycrystalline ferrite with randomly oriented grain boundaries suffers from the following problems.

FIGS. 12(a) and 12(b) are cross-sectional views used to explain defects of a structure of a thermoelectric conversion element according to an example of the prior art shown in Patent Literature 2. FIG. 12(a) shows a state of the thermoelectric conversion element prior to bending, and FIG. 12(b) shows a state of the thermoelectric conversion element that has been bent. FIG. 13 is a cross-sectional view showing a thermoelectric conversion element using a polycrystalline magnetic body with grain boundaries oriented in various directions according to another example of the prior art.

Referring to FIGS. 12(a) and 12(b), a thermoelectric conversion element 100 comprises a structure in which a monocrystalline ferrite layer 21 and an electromotive film 3 are stacked and formed in the order named on a substrate 4. The monocrystalline ferrite layer 21 and the electromotive film 3 form a power generation portion 11.

For example, even if the monocrystalline ferrite layer 21 and the electromotive film 3 are mounted on the substrate 4 of a flexible substrate as shown in Patent Literature 2, it is difficult to bend the thermoelectric conversion element to a large degree (i.e., to obtain a small bend radius) because the monocrystalline ferrite layer 21 has lower flexibility.

Furthermore, as shown in FIG. 12(b), when the thermoelectric conversion element 100 is bent, tensile stresses are applied to the electromotive film 3 whereas compressive stresses are applied to the substrate 4. Thus, large stresses are applied to a hard and fragile ferrite portion of the monocrystalline ferrite layer 21. As a result, cracks are generated in the monocrystalline ferrite layer 21. Accordingly, the thermoelectric conversion function may be impaired by breakage or the like.

Even if the monocrystalline ferrite layer 21 is not broken, the spin current scattering loss may be increased by such large stresses applied directly to the monocrystalline ferrite layer 21. Thus, thermoelectromotive forces may be reduced.

Furthermore, a monocrystalline ferrite has a relatively high thermal conductivity among insulating materials and is not suitable for a material that holds a large temperature difference in a thermoelectric conversion portion.

Additionally, growing a monocrystalline ferrite basically requires use of a surface of a substrate having lattice matching with a ferrite material or annealing in a high-temperature process. Therefore, it is difficult to deposit a monocrystalline ferrite on an organic film material or the like. No methods of manufacturing a flexible spin thermoelectric conversion element have been known so far.

Meanwhile, as shown in a cross-sectional view of FIG. 13, a thermoelectric conversion element 100 can be implemented by using a polycrystalline ferrite layer 22 formed of a polycrystalline ferrite with randomly arranged crystal grains or grain boundaries, instead of the monocrystalline ferrite layer 21 of the thermoelectric conversion element 100 shown in FIGS. 12(a) and 12(b). In this case, however, spin currents driven in a direction perpendicular to the surface is scattered at the grain boundaries by a temperature gradient. Therefore, it is difficult to achieve excellent conversion performance.

It is, therefore, an object of the present invention to provide a thermoelectric conversion element that can solve the aforementioned problems, can demonstrate thermoelectric conversion performance over elements using a monocrystalline ferrite, and also has flexibility or can be mounted on a surface having irregularities or a curved surface, a method of using such a thermoelectric conversion element, and a method of manufacturing such a thermoelectric conversion element.

### Means for Solving the Problems(s)

A thermoelectric conversion element according to one aspect of the present invention comprises a power generation portion comprising a columnar crystal ferrite layer and an electromotive film formed on the columnar crystal ferrite layer. The electromotive film is configured to generate an electromotive force in an in-plane direction by an inverse spin Hall effect. The columnar crystal ferrite layer comprises columnar crystal grains with a major axis a of 0.1 μm to 50 μm and a minor axis b of 0.01 μm to 1 μm.

In one aspect of the present invention, it is preferable to form the thermoelectric conversion element on a substrate having flexibility or directly on a heat source.

Furthermore, in one aspect of the present invention, it is preferable to form the columnar crystal ferrite layer of a spinel ferrite material MFe₂O₄. It is also preferable to form the columnar crystal ferrite layer by using a ferrite plating method.

Moreover, a method of manufacturing a thermoelectric conversion element according to another aspect of the present invention includes a step of forming a power generation portion, which includes a step of forming a columnar crystal ferrite layer comprising columnar crystal grains with a major axis a of 0.1 μm to 50 μm and a minor axis b of 0.01 μm to 1 μm by a ferrite plating manufacturing process, and a step of forming an electromotive film on the columnar crystal ferrite layer. The electromotive film is configured to generate an electromotive force in an in-plane direction by an inverse spin Hall effect.

In another aspect of the present invention, it is preferable to form the thermoelectric conversion element on a substrate having flexibility or directly on a heat source.

Furthermore, in another aspect of the present invention, it is preferable to form the columnar crystal ferrite layer of a spinel ferrite material MFe₂O₄. It is also preferable to form the columnar crystal ferrite layer by using a ferrite plating method.

### Advantageous Effects of Invention

According to the present invention, there can be provided a thermoelectric conversion element that can demonstrate thermoelectric conversion characteristics over elements using a monocrystalline ferrite, and also has flexibility or can be mounted on a surface having irregularities or a curved surface, a method of using such a thermoelectric conversion element, and a method of manufacturing such a thermoelectric conversion element.

### BRIEF DESCRIPTION OF DRAWINGS

FIG. 1 includes diagrams schematically showing a configuration of a thermoelectric conversion element using a columnar crystal ferrite according to a first embodiment of the present invention, in which (a) is a perspective view, and (b) is a partial enlarged cross-sectional view of the thermoelectric conversion element illustrated in (a).

FIG. 2 includes cross-sectional views showing the flexibility, which is an advantageous effect of the thermoelectric conversion element shown in FIGS. 1(a) and 1(b). In FIG. 2, (a) shows a state of the thermoelectric conversion element prior to bending, and (b) shows a state of the thermoelectric conversion element that has been bent.

FIG. 3 is a diagram modeling an electron microscope photograph showing a cross-section of a thermoelectric conversion element using a columnar crystal ferrite produced by a ferrite plating method illustrated in FIGS. 1(a) and 1(b).

FIG. 4 includes diagrams showing a thermoelectric conversion element formed on a polyimide substrate according to a specific example of the first embodiment of the present invention and measurement results of a thermoelectromotive force of the thermoelectric conversion element, in which (a) is a perspective view showing the thermoelectric conversion element, and (b) is a graph showing the measurement results of a thermoelectromotive force of the thermoelectric conversion element illustrated in (a).

FIG. 5 includes diagrams showing a thermoelectric conversion element formed on a polyimide substrate according to a specific example of the first embodiment of the present invention and the magnetic field dependency of a thermoelectromotive force of the thermoelectric conversion element, in which (a) is a perspective view showing the thermoelectric conversion element, and (b) is a graph showing the results of experiments for the magnetic field dependency of the thermoelectromotive force of the thermoelectric conversion element illustrated in (a).

FIG. 6 includes diagrams showing a multilayer thermoelectric conversion element using a columnar crystal ferrite according to the second embodiment of the present invention, in which (a) is a perspective view of the multilayer thermoelectric conversion element, and (b) is a partial enlarged cross-sectional view of (a).

FIG. 7 is a perspective view showing a thermoelectric conversion element according to a variation of the second embodiment of the present invention. FIG. 7 shows a multilayer thermoelectric conversion element produced by inserting buffer layers between the power generation portions shown in FIG. 6(a).

FIG. 8 is a cross-sectional view showing a thermoelectric conversion element according to a third embodiment of the present invention. FIG. 8 shows thermoelectric coating using a columnar crystal ferrite.

FIG. 9 is a cross-sectional view explanatory of an operative advantage of thermoelectric coating using a columnar crystal ferrite illustrated in FIG. 8.

FIG. 10 is a perspective view showing a thermoelectric conversion element according to a fourth embodiment of the present invention. FIG. 10 shows a thermoelectric conversion sheet using a columnar crystal ferrite.

FIG. 11 is a cross-sectional view showing an implementation example of the thermoelectric conversion sheet using a columnar crystal ferrite as shown in FIG. 10.

FIG. 12 includes cross-sectional views used to explain defects of a structure of a thermoelectric conversion element 100 according to an example of the prior art shown in Patent Literature 2, in which (a) shows a state of the thermoelectric conversion element prior to bending, and (b) shows a state of the thermoelectric conversion element that has been bent.

FIG. 13 is a cross-sectional view showing a thermoelectric conversion element using a polycrystalline magnetic body with grain boundaries oriented in various directions according to another example of the prior art.

### MODE(S) FOR CARRYING OUT THE INVENTION

Embodiments of the present invention will be described below.

### First Embodiment

A first embodiment of the present invention describes a flexible thermoelectric conversion element.

The inventors have found that a flexible thermoelectric conversion element demonstrating performance that is equivalent to the performance of a thermoelectric conversion element using a monocrystalline ferrite can be formed by use of a columnar crystal ferrite material.

Here, columnar crystal refers to a crystalline structure in which each crystal grain of a film comprises a columnar shape that is elongated in the perpendicular-plane direction. With such a columnar crystal film, scattering factors that inhibit thermal spin current driving in the perpendicular-plane direction are reduced as compared to a polycrystalline film having randomly oriented grain boundaries. Therefore, such a columnar crystal film has been found to be preferable for a magnetic film used for a thermoelectric conversion element using the spin Seebeck effect.

Furthermore, large grain boundaries extending along the perpendicular-plane direction in a columnar crystal ferrite layer serve as a cushion that absorbs bending stresses. Therefore, the element has been found to have high flexibility.

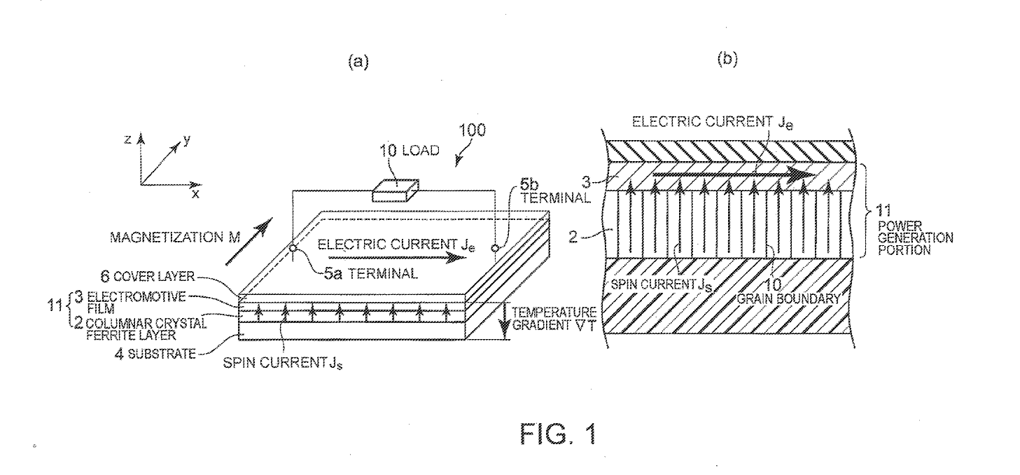

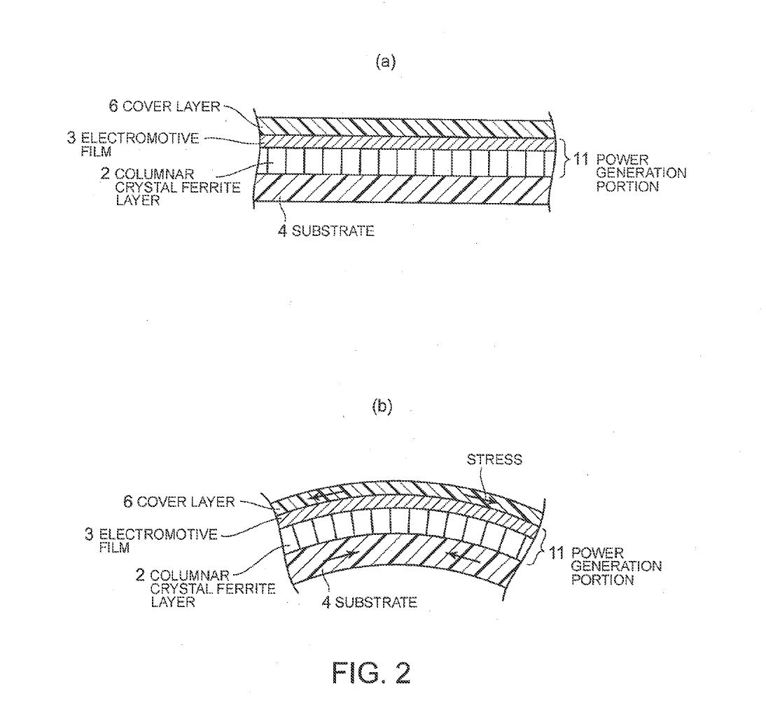

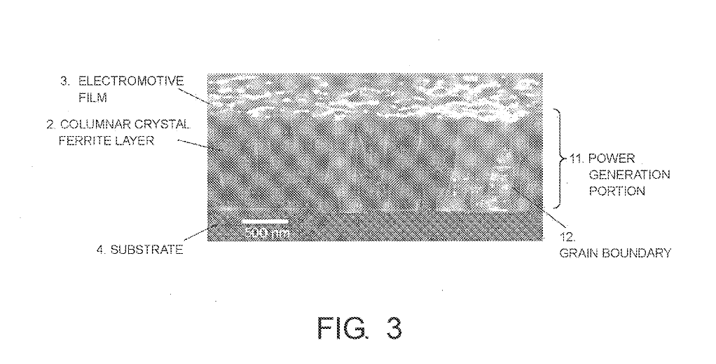

FIG. 1(a) is a perspective view schematically showing a configuration of a thermoelectric conversion element 100 according to a first embodiment of the present invention, and FIG. 1(b) is a partial enlarged cross-sectional view of FIG. 1(a). FIGS. 2(a) and 2(b) are cross-sectional views showing the flexibility, which is an advantageous effect of the thermoelectric conversion element shown in FIGS. 1(a) and 1(b). FIG. 2(a) shows a state of the thermoelectric conversion element prior to bending, and FIG. 2(b) shows a state of the thermoelectric conversion element that has been bent. FIG. 3 is a diagram modeling an electron microscope photograph showing a cross-section of a thermoelectric conversion element using a columnar crystal ferrite produced by a ferrite plating method illustrated in FIGS. 1(a) and 1(b).

As shown in FIGS. 1(a) and 1(b), the thermoelectric conversion element 100 includes an electromotive film 3, a columnar crystal ferrite layer 2, and a substrate 4 that supports the electromotive film 3 and the columnar crystal ferrite layer 2.

The columnar crystal ferrite layer 2 is formed on the substrate 4, and the electromotive film 3 is formed in contact with the columnar crystal ferrite layer 2. In other words, the substrate 4, the columnar crystal ferrite layer 2, and the electromotive film 3 are stacked in the order named. This stacking direction is referred to as the perpendicular-plane direction or the z-direction. The in-plane directions, which are perpendicular to the z-direction, are the x-direction and the y-direction. The x-direction and the y-direction are perpendicular to each other.

In this example, a power generation portion 11, which is formed by a stacking structure of the columnar crystal ferrite layer 2 and the electromotive film 3, bears a thermoelectric conversion operation. An electromotive force is derived from terminals 5a and 5b provided on opposite sides of the electromotive film 3.

The columnar crystal ferrite layer 2 serves as a spin current generation portion, which demonstrates the spin Seebeck effect. The columnar crystal ferrite layer 2 generates (drives) a spin current Js from a temperature gradient ∇T applied in the perpendicular-plane direction by the spin Seebeck effect. The direction of the spin current Js being driven is in parallel to and is the same as or opposite to the direction of the temperature gradient ∇T.

In the example illustrated in FIGS. 1(a) and 1(b), a temperature gradient ∇T is applied in the +z-direction, so that a spin current is generated along the +z-direction or −z-direction.

According to Non-Patent Literature 2, in a case where the columnar crystal ferrite layer 2 has a thickness of not more than 200 nm, the resultant thermopower becomes lower as the film thickness is smaller. Therefore, the columnar crystal ferrite layer 2 preferably has a film thickness of at least 200 nm. Additionally, columnar crystal grains preferably comprise an elongated shape from the viewpoint of the performance improvement, which will be described later, and the flexibility. In other words, preferably, a>b where the height of a columnar crystal grain (major axis) is defined by a and the thickness of the columnar crystal grain (minor axis) is defined by b.

Use of a ferrite plating method, which will be described later, can provide a columnar crystal ferrite layer 2 in which crystal is columnar while the major axis a of the columnar crystal is in a range of 0.1 μm to 50 μm and the minor axis b of the columnar crystal is in a range of 0.01 μm to 1 μm.

Furthermore, columnar crystal grains do not necessarily comprise an ideal cylindrical shape. Thus, the columnar crystal grains may slightly be inclined obliquely, or the thickness of the columnar crystal grains may be different from the bottom to the top. In the former case of the inclined cylindrical shape, the major axis a is defined by the height measured along a direction perpendicular to the film surface (corresponding to the film thickness). In the latter case of the cylindrical shape having varied thicknesses, the minor axis b is defined by an average of the thickness.

In order to demonstrate this spin Seebeck effect, the columnar crystal ferrite layer 2 should have magnetization. The direction of the magnetization is preferably in the in-plane direction and is perpendicular to a direction in which an electromotive force is derived (a direction connecting the terminal 5a and the terminal 5b to each other).

In the first embodiment of the present invention, the columnar crystal ferrite layer 2 has magnetization M oriented in the +y-direction. In order to operate the thermoelectric conversion element stably, it is preferable to use a ferrite material that stably holds this magnetization M. The coercive force H_{c}, which is an index for the strength of holding magnetization, is preferably in such a range that H_{c}>0.8 KA/m. Furthermore, in order to enhance the coercive force, a hard magnet or a magnetic film having a large coercive force may be arranged close to the columnar crystal ferrite layer 2.

Furthermore, it is preferable to use the columnar crystal ferrite layer 2 at temperatures not more than the Curie temperature T_{C}, which can hold the magnetization, because the magnetization is required. Specifically, it is preferable to establish T_{C}>T_{H} where a higher temperature applied to the thermoelectric conversion element is defined by T_{H}.

In the first embodiment of the present invention, a spinel ferrite material having a composition of MFe₂O₄ is produced as a material for the columnar crystal ferrite layer 2 on the substrate 4 by a ferrite plating method. Here, M represents a metal element, such as Ni, Zn, Co, Mn, or Fe.

A ferrite plating method includes:

(i) bringing an aqueous solution containing Ni²⁺, Zn²⁺, Fe²⁺ ions, or the like into contact with a surface of a substrate to adsorb metal hydroxide ions;

(ii) then oxidizing those ions with an oxidant (Fe²⁺→Fe³⁺); and

(iii) further causing a ferrite crystallization reaction to those ions with the metal hydroxide ions in the aqueous solution to form a ferrite film on the surface of the substrate.

The processes described at (i) to (iii) are sequentially repeated to form a ferrite film having a film thickness of 0.2 μm to 50 μm.

This ferrite plating involves a deposition process of crystallizing one layer by one layer from a surface of a substrate. Therefore, grain boundaries are more unlikely to be produced in an in-plane direction than in a perpendicular-plane direction. In other words, a columnar crystal structure having elongated crystal grains is produced by the plating process. Typically, a crystal structure produced by ferrite plating comprises columnar crystal in which the length of crystal grains (major axis) is approximately a=0.2 μm to 50 μm and the thickness of crystal grains (minor axis) is approximately b=20 nm to 500 nm.

FIG. 3 is a diagram modeling an electron microscope photograph of an actual thermoelectric conversion element produced by a ferrite plating method. As shown in FIG. 3, columnar crystal in which a major axis a=1 μm and a minor axis b=100 nm was formed.

The Curie temperature T_{C} of the spinel ferrite material MFe₂O₄ according to the first embodiment of the present invention is typically in a range of about 200° C. to about 400° C. In a case where a high Curie temperature T_{C} is required, it is preferable to include, as M, a magnetic element such as Ni, Co, Fe, or the like. For example, (Ni, Zn)Fe₂O₄ can obtain a higher Curie temperature as compared to a garnet ferrite material reported in Non-Patent Literature 2 and the like.

Furthermore, in order to hold magnetization in an optimum direction (in a direction on the plane that is perpendicular to a direction in which an electromotive force is derived), magnetic anisotropy can be generated in the columnar crystal ferrite layer 2 by applying an external magnetic field during the aforementioned manufacturing processes (i) to (iii).

Specifically, an external magnetic field of about 8 KA/m to about 80 KA/m is applied in a direction corresponding to the y-axis shown in FIG. 1(a) during the ferrite plating formation, making the y-axis an easy axis of magnetization for the columnar crystal ferrite layer 2. Furthermore, this method also demonstrates effects of increasing residue magnetization when a magnetic field is changed to zero after initialization of the magnetization. This makes magnetization of the element likely to be held in an optimal direction. Therefore, the operational reliability of the thermoelectric conversion element can be enhanced. In order to obtain high magnetic anisotropy with this method, it is preferable to include Co as the metal element M.

The electromotive film 3 serves as a spin/electric-current conversion portion that demonstrates the inverse spin Hall effect. Specifically, the electromotive film 3 generates an electric current Je from the spin current Js by the inverse spin Hall effect. The direction of the generated electromotive force is given by an outer product of a direction of the magnetization M of the ferrite film 2 and a direction of the temperature gradient ∇T(Je∝M×∇T).

In the first embodiment of the present invention shown in FIGS. 1(a) and 1(b), the direction of the magnetization M of the columnar crystal ferrite layer 2 is the +y-direction, and the direction of the temperature gradient ∇T is the +z-direction. Therefore, the electric current Je is generated in the +x-direction.

A material including atoms that exhibit high “spin-orbit interaction” is used for the electromotive film 3. For example, Pt, Au, Ir, Pd, Ag, Bi, W, other metals having an f-orbit, or alloys including any of those elements may be used for the electromotive film 3. For example, an alloy material including a base metal such as Cu and a small amount of an impurity of a heavy element such as Ir or Bi may be used for the electromotive film 3. From the viewpoint of the efficiency of deriving electric power, the film thickness of the electromotive film 3 is preferably equal to or less than about the “spin diffusion length (spin relaxation length),” which depends upon materials. For example, when the electromotive film 3 is a Pt film, it is preferable to set the film thickness of the electromotive film 3 to be equal to or approximately equal to the spin diffusion length of Pt, or less than the spin diffusion length of Pt, i.e., about 1 nm to 30 nm.

The terminal 5a and the terminal 5b are electrically connected to opposite ends of the electromotive film 3, respectively. The terminal 5a and the terminal 5b serve to output an electromotive force generated in the electromotive film 3. Therefore, when a load 10 is connected to those terminals as shown in FIG. 1(a), electric power can be supplied to the load 10. From the viewpoint of impedance matching for supply maximum electric power, it is preferable for an internal resistance of the electromotive film 3 between the terminal 5a and the terminal 5b to be approximately the same as an external resistance of the load 10, to which electric power is supplied.

Furthermore, according to the first embodiment of the present invention, a flexible substrate is used as the substrate 4. For example, it is preferable to use an organic resin substrate such as a polyimide substrate or a polyester substrate. The preferable film thickness of the substrate 4 depends upon the intended use or the application. Generally, when an organic resin is used, the thermal conductivity of the material is low. Therefore, it is preferable for the substrate 4 to have a film thickness not more than 30 μm in order to apply a temperature difference effectively to the power generation portion 11.

In the first embodiment of the present invention, the cover layer 6 is provided above the electromotive film 3. In this example, it is preferable to use a material having flexibility as the material for the cover layer 6. For example, it is preferable to use an organic resin material such as polyimide or polyester. The cover layer 6 does not need to be provided in order to provide a thermoelectric conversion function.

With the aforementioned structure, there can be provided a thermoelectric conversion element that can achieve both of (1) thermoelectric conversion performance over an element using a monocrystalline ferrite and (2) high flexibility.

There will be described operative advantages of the thermoelectric conversion element according to the first embodiment of the present invention.

A first operative advantage is an improvement of the thermoelectric conversion performance.

For a thermoelectric conversion element using the spin Seebeck effect, it is preferable to have excellent spin-current propagation characteristics and low thermal conduction characteristics in order to perform satisfactory power generation with a temperature difference being held. However, conventional elements using a monocrystalline ferrite or a polycrystalline ferrite have difficulty in achieving those demands simultaneously.

Satisfactory spin-current propagation characteristics that are equivalent to those obtained with monocrystal can be expected with a columnar crystal structure. In the columnar crystal ferrite layer 2, a spin current Js driven by a temperature gradient ∇T and the grain boundaries 12 are in parallel to each other (both in the perpendicular-plane direction).

Therefore, in a case of the spin-current propagation (spin currents propagating through microscopic interaction between localized electron spins) in a ferrite, which is an insulating material, a probability that a grain boundary 12 along such a propagation direction scatters the spin current is low. Accordingly, the grain boundary 12 does not greatly inhibit the propagation of the spin currents Js. Thus, it is possible to obtain satisfactory spin current propagation characteristics that are equivalent to those obtained when a monocrystalline ferrite is used.

Meanwhile, the propagation characteristics of phonons, which bear thermal conduction, are greatly impaired with a columnar crystal structure. When the minor axis b of crystal grains becomes a nano-scale of several tens of nanometers to several hundreds of nanometers, the size of the structure is smaller than the mean free path of phonons. Therefore, the probability that phonons are backscattered increases in the grain boundaries 12 of the ferrite layer. Thus, the thermal conductivity is lowered. In other words, it becomes easy to hold a temperature difference by a large thermal resistance. In this case, the minor axis b of crystal grains should preferably be such that b<500 nm, more preferably be such that b<200 nm.

In this manner, an electrothermal material (ferrite) according to the present invention can obtain both of high spin current conductivity that is equivalent to that obtained with monocrystal and thermal conductivity that is lower than that obtained with monocrystal. Therefore, high thermoelectric conversion performance can be achieved.

A second operative advantage is achievement of high flexibility.

Additionally, high flexibility can be achieved by a columnar crystal structure. The grain boundaries 12 in the columnar crystal ferrite layer 2 serve as a cushion for absorbing bending stresses. Therefore, breakage of the ferrite layer upon bending or lowered conversion performance due to stresses is unlikely to occur. Thus, a thermoelectric conversion element with high flexibility can readily be achieved.

Furthermore, the cover layer 6 serves to protect the power generation portion 11 from external damage factors and also serves to weaken bending stresses applied to the power generation portion 11.

As shown in FIGS. 2(a) and 2(b), when the thermoelectric conversion element 100 is bent, a tensile stress is applied to the overlaid cover layer 6 while a compressive stress is applied to the substrate 4. A stress applied to the inner power generation portion 11 can be made relatively low. Thus, the reliability of the flexible thermoelectric conversion element can further be enhanced.

In order to maintain such high flexibility, it is preferable for crystal grains in the columnar crystal ferrite layer 2 to comprise such an elongate shape that the major axis a>the minor axis b.

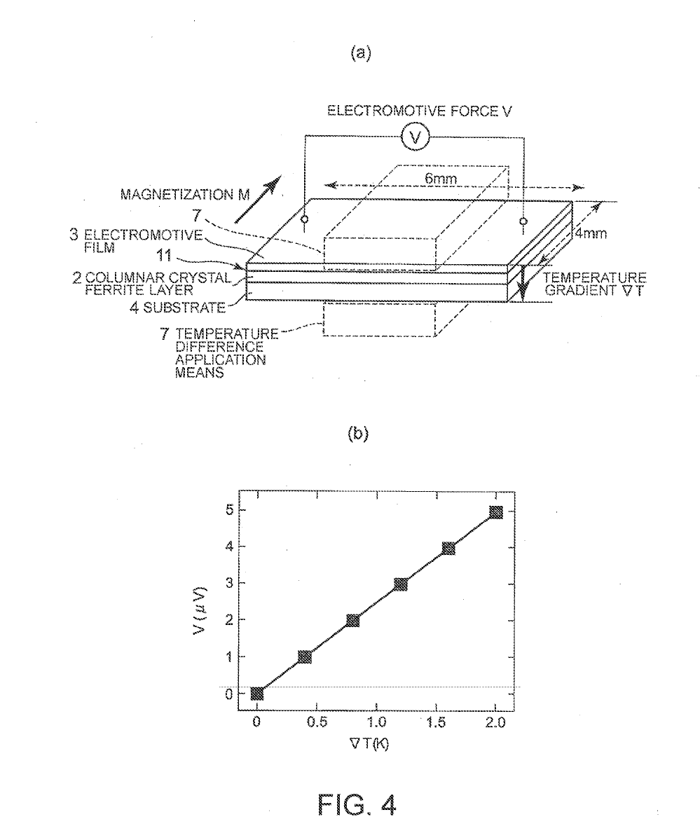

Next, a specific example of the thermoelectric conversion element according to the first embodiment of the present invention will be described based upon FIGS. 4(a) and 4(b).

FIG. 4(a) is a perspective view showing a thermoelectric conversion element formed on a polyimide substrate according to a specific example of the first embodiment of the present invention, and FIG. 4(b) is a graph showing the measurement results of a thermoelectromotive force of the thermoelectric conversion element illustrated in FIG. 4(a).

In the example of the present invention, a polyimide substrate having a thickness of 25 μm was used as the substrate 4, Ni_{0.2}Zn_{0.3}Fe_{0.5}Fe₂O₄ having a thickness of 3 μm was used as the columnar crystal ferrite layer 2, and Pt having a film thickness of 10 nm was used as the electromotive film 3.

In the example of the present invention, Ni_{0.2}Zn_{0.3}Fe_{0.5}Fe₂O₄ having a film thickness of 3 μm was produced on the polyimide substrate by the aforementioned ferrite plating method. Furthermore, Pt having a film thickness of 10 nm was deposited as the electromotive film 3 on an upper surface of Ni_{0.2}Zn_{0.3}Fe_{0.5}Fe₂O₄ by a sputtering method. The width of the element was 4 mm, and the length of the element was 6 mm. A temperature difference ΔT was applied to this element by using temperature application means 7 to generate a thermoelectromotive force V, which is in proportion to ΔT.

The resultant electromotive force per unit temperature difference was V/ΔT=2.5 μV/K. A larger value was obtained as compared to an element using monocrystal or a ferrite similar to monocrystal, which has heretofore been reported (Non-Patent Literature 2). This probably suggests that both of spin current conductivity that is equivalent to that of monocrystal and thermal conductivity that is lower than that of monocrystal could be obtained in an element using a columnar crystal ferrite according to the present invention.

In order to examine a coercive force of this element, the dependency of the thermoelectromotive force upon an external magnetic field was also evaluated.

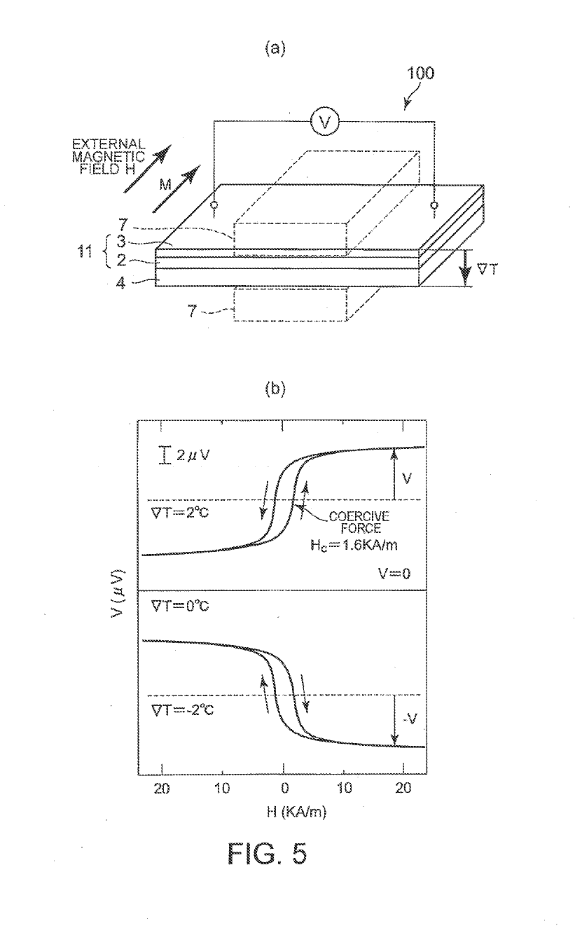

FIG. 5(a) is a perspective view showing a thermoelectric conversion element formed on a polyimide substrate according to a specific example of the first embodiment of the present invention, and FIG. 5(b) is a graph showing the results of experiments for the magnetic field dependency of the thermoelectromotive force of the thermoelectric conversion element illustrated in FIG. 5(a).

As shown in FIGS. 5(a) and 5(b), it is confirmed that, when an external magnetic field H was applied to the element, the magnetization of the ferrite Ni_{0.2}Zn_{0.3}Fe_{0.5}Fe₂O₄ changed along the direction of the external magnetic field so that the thermoelectromotive force V was changed and that the sign thereof was inversed. A coercive force He evaluated from those results was H_{C}=1.6 KA/m.

### Second Embodiment

A multilayer thermoelectric conversion element will be described in a second embodiment of the present invention.

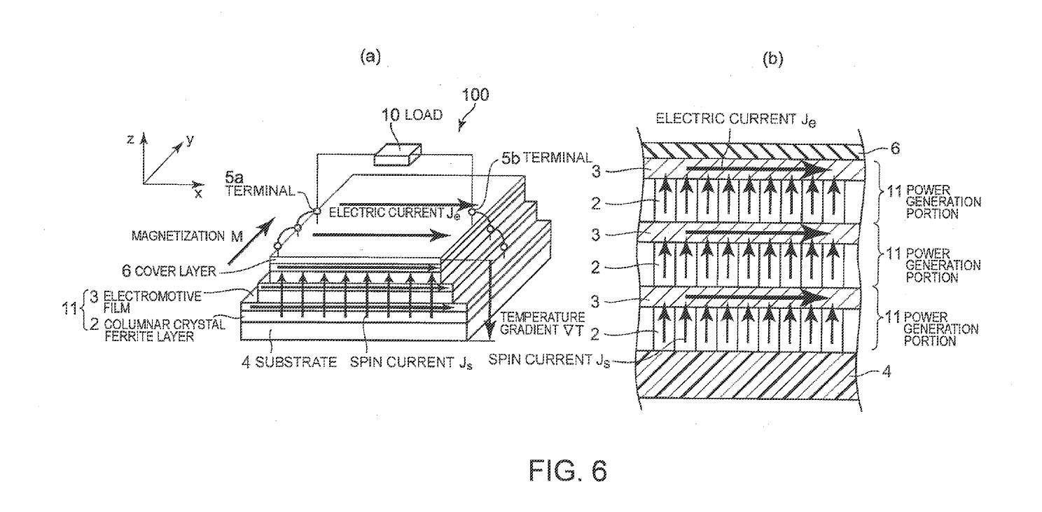

FIG. 6(a) is a perspective view showing a multilayer thermoelectric conversion element using a columnar crystal ferrite according to the second embodiment of the present invention, and FIG. 6(b) is a partial enlarged cross-sectional view of FIG. 6(a).

In the first embodiment, there is provided only one layer of the power generation portion 11 including the columnar crystal ferrite layer 2 and the electromotive film 3. If the film thickness of the columnar crystal ferrite layer 2 and the electromotive film 3 is small, it is difficult to hold a large temperature difference. Therefore, a high electric power cannot be obtained.

As shown in FIGS. 6(a) and 6(b), in the second embodiment of the present invention, a plurality of layers of the power generation portions 11 are stacked to form a thermoelectric conversion element that can output a higher electric power.

In a case of a thermoelectric conversion element using a monocrystalline ferrite, which has heretofore been reported, an underlying layer having high lattice matching for crystal growth and a heating process are required. Therefore, it is difficult to form a multilayered structure. In contrast, according to a columnar crystal ferrite of the present invention, a film can satisfactorily be formed, for example, on a surface of the electromotive film 3 or on any buffer layer by using a ferrite plating method.

Referring to FIGS. 6(a) and 6(b), in the thermoelectric conversion element 100 according to the second embodiment of the present invention, three layers of the power generation portions 11, each of which is the same as the power generation portion 11 of the first embodiment, are stacked to produce a multilayer structure. With this multilayered structure, an electric current can be output from each of the three electromotive films 3. Therefore, when those electromotive films 3 are electrically connected in parallel and connected to an external load 10, a higher electric power can be supplied to the load 10.

### (Variation)

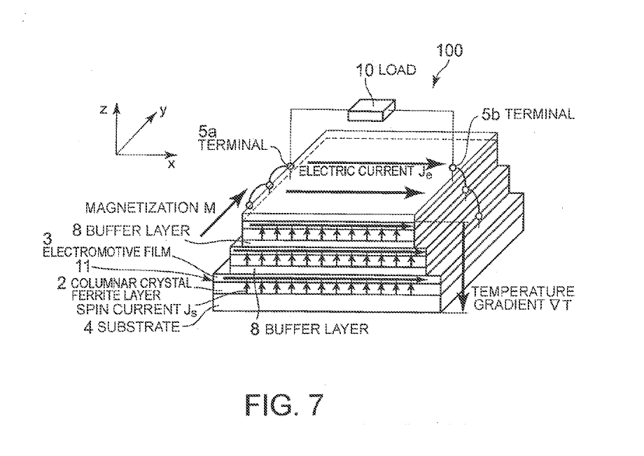

FIG. 7 is a perspective view showing a thermoelectric conversion element according to a variation of the second embodiment of the present invention. FIG. 7 shows a multilayer thermoelectric conversion element produced by inserting buffer layers between the power generation portions shown in FIG. 6(a).

As shown in FIG. 7, in the thermoelectric conversion element 100 according to the variation, buffer layers 8 may be inserted between the power generation portions 11. When an organic resin material having a high resilience is used as the buffer layers 8, distortion stresses are advantageously prevented from remaining when a ferrite plating film is thickened. For this purpose, it is preferable to use an organic resin material such as polyimide or polyester.

### Third Embodiment

A thermoelectric conversion coating to a heat source comprising a curved surface or a surface with irregularities will be described in a third embodiment of the present invention.

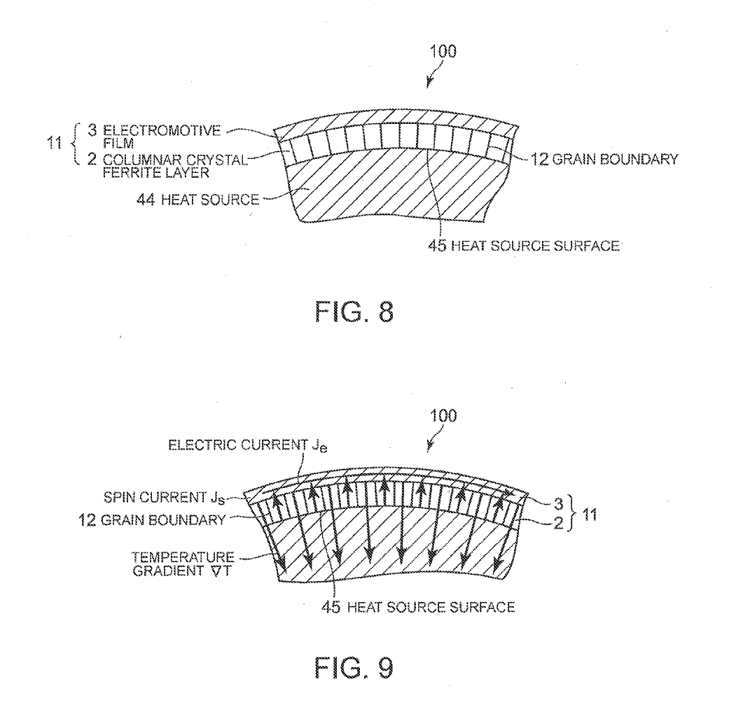

FIG. 8 is a cross-sectional view showing a thermoelectric conversion element according to the third embodiment of the present invention. FIG. 8 shows thermoelectric coating using a columnar crystal ferrite. FIG. 9 is a cross-sectional view explanatory of an operative advantage of thermoelectric coating using a columnar crystal ferrite illustrated in FIG. 8.

The third embodiment of the present invention illustrates thermoelectric coating to a heat source having a curved surface or a surface with irregularities. For a heat source having a curved surface or a surface with irregularities, a flexible thermoelectric conversion element as shown in the first embodiment may be arranged along the surface of the heat source. Nevertheless, the same effects can also readily be attained by a method of directly coating the columnar crystal ferrite layer 2 and the electromotive film 3 on the heat source (thermoelectric coating).

As shown in FIG. 8, in the third embodiment of the present invention, a power generation portion 11 including a columnar crystal ferrite layer 2 and an electromotive film 3 is directly coated on a heat source 44 comprising a curved surface for thereby performing thermoelectric conversion.

The columnar crystal ferrite layer 2 is produced directly on the heat source 44 by using a ferrite plating method. When a ferrite plating film is deposited on such a curved surface, each of crystal grains grows perpendicular to a local surface of the heat source. As a result, even in the case of the heat source 44 comprising a curved surface, every grain boundary 12 is perpendicular to the heat source surface 45 as shown in FIG. 8.

Therefore, assuming that the temperature of the heat source 44 is constant, a temperature gradient ∇T is also generated perpendicular to the heat source surface 45 as shown in FIG. 9. Accordingly, the temperature gradient ∇T, a spin current Js driven by the temperature gradient ∇T, and the grain boundaries 12 are locally perpendicular to each other. Thus, the grain boundaries 12 do not greatly inhibit propagation of the spin current Js, and a satisfactory thermoelectric conversion operation can be expected.

### Fourth Embodiment

A thermoelectric conversion tape, as a thermoelectric conversion element, attachable externally to a heat source will be described in a fourth embodiment of the present invention.

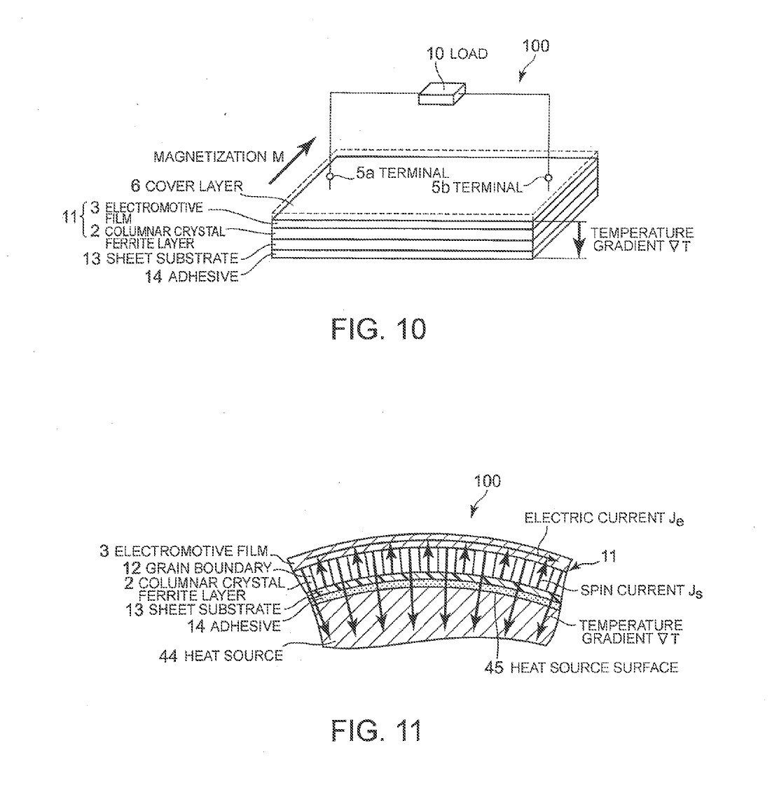

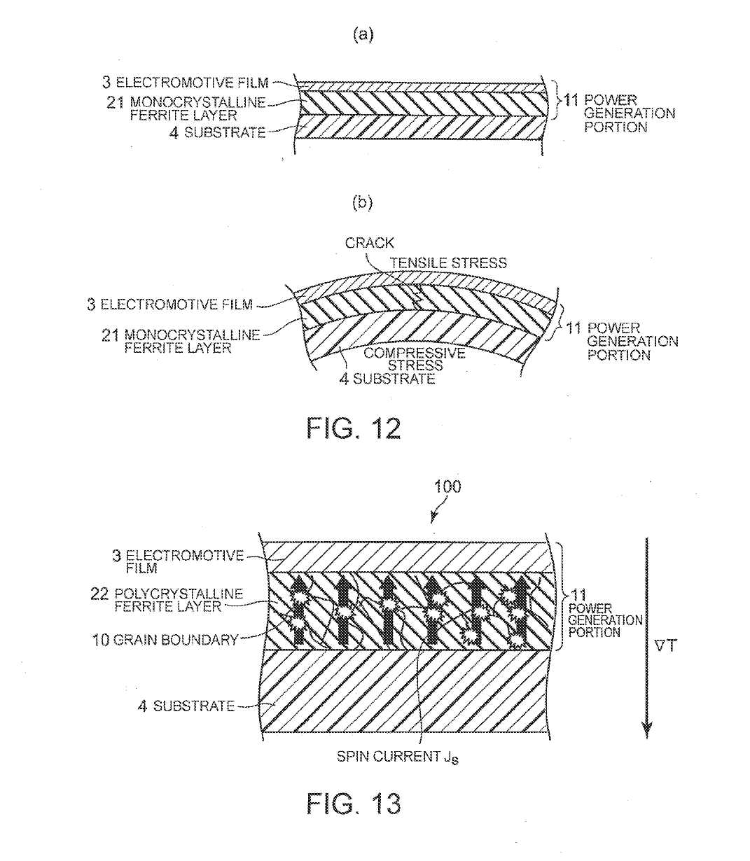

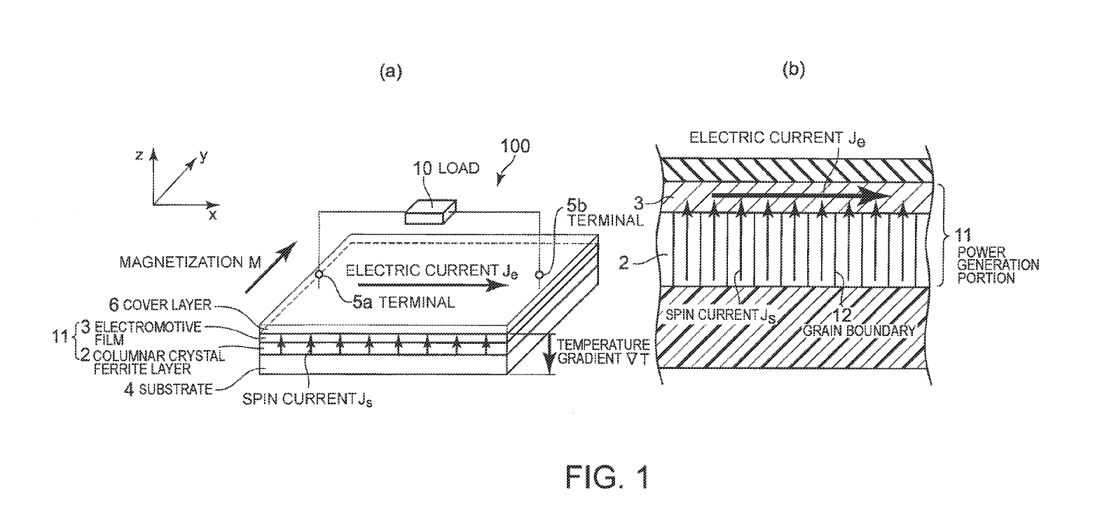

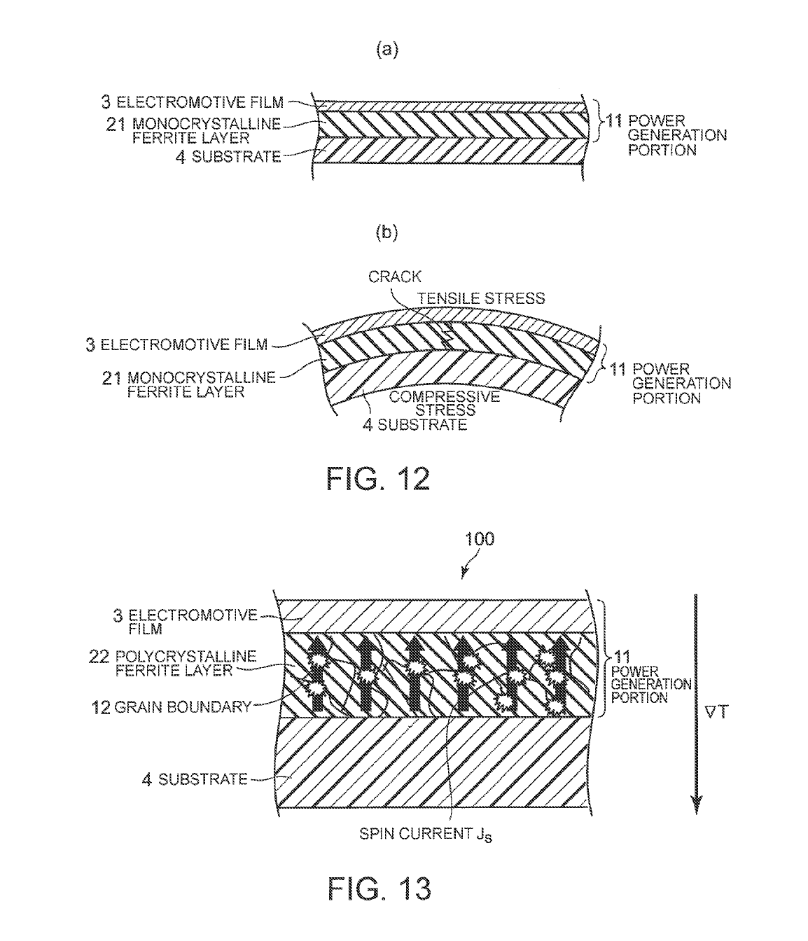

FIG. 10 is a perspective view showing a thermoelectric conversion element according to the fourth embodiment of the present invention. FIG. 10 shows a thermoelectric conversion sheet using a columnar crystal ferrite. FIG. 11 is a cross-sectional view showing an implementation example of the thermoelectric conversion sheet using a columnar crystal ferrite as shown in FIG. 10.

As shown in FIG. 10, a thermoelectric conversion tape as the thermoelectric conversion element 100 comprises a power generation portion 11 including a columnar crystal ferrite layer 2 and an electromotive film 3, a sheet substrate 13, and an adhesive 14.

The same material as used in a conventional thermoelectric conversion element is used for the power generation portion 11. It is preferable to use a thin film with flexibility for the sheet substrate 13. It is preferable to use an organic resin material having a film thickness of 30 μm or less.

The adhesive 14 is formed of a material having stickiness. The adhesive 14 allows the thermoelectric conversion element to be attached directly to variety types of heat sources.

As shown in FIG. 11, the entire thermoelectric conversion element according to the fourth embodiment of the present invention has flexibility. Therefore, the thermoelectric conversion element can flexibly be applied to a heat source 44 comprising a curved surface. In this case, as with the third embodiment of the present invention, every grain boundary 12 is perpendicular to the heat source surface 45. Accordingly, spin currents are not scattered such that satisfactory thermoelectric conversion performance can be obtained.

### INDUSTRIAL APPLICABILITY

As described above, a thermoelectric conversion element according to the present invention is applied to a thermoelectric generator element and a temperature sensor such as a thermocouple.

### DESCRIPTION OF REFERENCE NUMERALS AND SIGNS

2 columnar crystal ferrite layer
3 electromotive film
4 substrate
5a, 5b terminal
6 cover layer
7 temperature difference application means
8 buffer layer
10 load
11 power generation portion
12 grain boundary
13 sheet substrate
14 adhesive
44 heat source
45 heat source surface
100 thermoelectric conversion element

This application claims the benefit of priority from Japanese patent application No. 2012-267483, filed on Dec. 6, 2012, the disclosure of which is incorporated herein in its entirety by reference.

1. A thermoelectric conversion element including a power generation portion comprising a columnar crystal ferrite layer and an electromotive film formed on the columnar crystal ferrite layer, the electromotive film being configured to generate an electromotive force in an in-plane direction by an inverse spin Hall effect,
the columnar crystal ferrite layer comprising columnar crystal grains with a major axis a of 0.1 μm to 50 μm and a minor axis b of 0.01 μm to 1 μm.

2. The thermoelectric conversion element as recited in claim 1, wherein the columnar crystal ferrite layer has magnetization in the in-plane direction.

3. The thermoelectric conversion element as recited in claim 1, wherein:
the columnar crystal ferrite layer includes a spinel ferrite material represented by a general expression: MFe₂O₄.

4. The thermoelectric conversion element as recited in claim 1, wherein:
the columnar crystal ferrite layer is formed by a ferrite plating manufacturing process.

5. The thermoelectric conversion element as recited in claim 4, wherein:
in the ferrite plating manufacturing process, magnetization is initialized while an external magnetic field is applied.

6. The thermoelectric conversion element as recited in claim 1, wherein:
the columnar crystal ferrite layer and the electromotive film are formed on a substrate having flexibility.

7. The thermoelectric conversion element as recited in claim 1, comprising a multilayer structure in which a plurality of the power generation portions are stacked.

8. The thermoelectric conversion element as recited in claim 7, comprising a buffer layer formed between the plurality of the power generation portions.

9. A method of using the thermoelectric conversion element as recited in claim 1,
forming the columnar crystal ferrite layer and the electromotive film directly on a surface of a heat source such that grain boundaries of the columnar crystal ferrite layer extend upward from the surface of the heat source for using the thermoelectric conversion element.

10. The method of using the thermoelectric conversion element as recited in claim 6, bringing the thermoelectric conversion element having flexibility into close contact with a surface of the heat source with adhesive means such that grain boundaries of the columnar crystal ferrite layer extend upward from the surface of the heat source.

11. A method of manufacturing a thermoelectric conversion element, comprising:
forming a power generation portion, which includes:
forming a columnar crystal ferrite layer comprising columnar crystal grains with a major axis of 0.1 μm to 50 μm and a minor axis b of 0.01 μm to 1 μm by a ferrite plating manufacturing process, and
forming an electromotive film on the columnar crystal ferrite layer,
wherein the electromotive film is configured to generate an electromotive force in an in-plane direction by an inverse spin Hall effect,

12. The method of manufacturing a thermoelectric conversion element as recited in claim 11, wherein:
in the ferrite plating manufacturing process, magnetization is initialized while an external magnetic field is applied.

13. The method of manufacturing a thermoelectric conversion element as recited in claim 11, forming the columnar crystal ferrite layer such that the columnar crystal ferrite layer has magnetization in an in-plane direction.

14. The method of manufacturing a thermoelectric conversion element as recited in claim 11, using a spinel ferrite material represented by a general expression MFe₂O₄ for the columnar crystal ferrite layer.

15. The method of manufacturing a thermoelectric conversion element as recited in claim 11, forming the columnar crystal ferrite layer and the electromotive film on a substrate having flexibility.

16. The method of manufacturing a thermoelectric conversion element as recited in claim 11, comprising repeating forming the power generation portion to stack a plurality of the power generation portions for forming a multilayer structure.

17. The method of manufacturing a thermoelectric conversion element as recited in claim 16, forming the multilayer structure such that a buffer layer is formed between the plurality of the power generation portions.
